(19) United States
(12) Patent Application Publication
(10) Pub. No.: US 2015/0302913 A1
(43) Pub. Date: Oct. 22, 2015

(54) VOLATILE MEMORY DEVICE, MEMORY MODULE INCLUDING THE SAME, AND METHOD OF OPERATING MEMORY MODULE

(71) Applicant: Choung-Ki SONG, Gyeonggi-do (KR)

(72) Inventor: Choung-Ki SONG, Gyeonggi-do (KR)

(21) Appl. No.: 14/486,529

(22) Filed: Sep. 15, 2014

(30) Foreign Application Priority Data
Apr. 17, 2014 (KR) 10-2014-0045920

(51) Int. Cl. G11C 11/406; G11C 11/408; G11C 11/4074

(52) U.S. Cl. CPC G11C 11/406; G11C 11/4074; G11C 11/4087

(57) ABSTRACT

A memory module includes an emergency power; a volatile memory device including a plurality of memory blocks; a nonvolatile memory device; and a module control block suitable for controlling data of the volatile memory device to be backed up to the nonvolatile memory device by using the emergency power when a power failure occurs, wherein data of the memory blocks are sequentially backed up to the nonvolatile memory device, and a refresh operation prohibited for a memory block of which back up is completed.

### CROSS-REFERENCE TO RELATED APPLICATIONS

The present application claims priority of Korean Patent Application No. 10-2014-0045920, filed on Apr. 17, 2014, which is incorporated herein by reference in its entirety.

### BACKGROUND

1. Field

Various embodiments of the present invention relate to a volatile memory device and a memory module including the same.

2. Description of the Related Art

A memory cell of a volatile memory, for example, a DRAM, includes a transistor that serves as a switch and a capacitor that stores charges corresponding to data. Whether data is high (i.e., a logic 1) or low (i.e., a logic 0) is determined according to the amount of charge that is charged in the capacitor of a memory cell, (i.e., whether or not the voltage of the terminal of the capacitor is high or low).

Since retention of data is implemented in such a manner that charges are accumulated in the capacitor, power consumption does not occur in principle. However, because an initial amount of charge stored in the capacitor diminishes due to leakage current caused by the PN junction of an MOS transistor or the like, data may be lost. To prevent the data from being lost, the data in the memory cell should be read and recharged to in conformity with the information read, before the data is lost. The memory of the data is retained only when such an operation is periodically repeated. Such a recharging process of cell charges is referred to as a refresh operation.

The memory chips mounted in most memory modules, which are used in a data processing system such as a personal computer (PC), a work station, a server computer or a communication system, are volatile memories. While volatile memories may operate at a high speed, they have a disadvantage in that data may be lost if power is blocked since a refresh operation may not be performed when not powered. Recently, to cope with such a disadvantage, a memory module of a non-volatile dual in-line memory module (NVDIMM) scheme has been adopted. The NVDIMM includes a volatile memory, a nonvolatile memory and an emergency power. The NVDIMM may prevent data from being lost due to a host power failure, through an operation of backing up the data of the volatile memory to the nonvolatile memory by using the emergency power when the power of a host is unstable.

Generally, a power capacitor is used for emergency power mounted in an NVDIMM. However, an increase in the capacity of the power capacitor used as the emergency power is directly related with an increase in cost. Therefore, a technology that is capable of safely backing up the data of a volatile memory to a nonvolatile memory while using a small amount of power is in demand.

### SUMMARY

Various embodiments are directed to a technology that may reduce power consumption for backing up the data of a volatile memory to a nonvolatile memory.

In an embodiment, a volatile memory device may include: a plurality of memory blocks suitable for being refreshed in response to a plurality of refresh signals, respectively; a command decoder suitable for decoding a command to generate an internal refresh command; and a refresh circuit suitable for generating the refresh signals in response to the internal refresh command, wherein the refresh circuit prohibits a refresh signal corresponding to a memory block of which back up is completed from activating.

In an embodiment, a memory module may include: an emergency power; a volatile memory device including a plurality of memory blocks; a nonvolatile memory device; and a module control block suitable for controlling data of the volatile memory device to be backed up to the nonvolatile memory device by using the emergency power when a power fall occurs, wherein data of the memory blocks are sequentially backed up to the nonvolatile memory device, and a refresh operation is prohibited for a memory block of which back up is completed.

In an embodiment, a method of operating a memory module, including a volatile memory device and a nonvolatile memory device, may include: sensing a fail of a host power; converting a power to be used by the memory module, from the host power to an emergency power; backing up sequentially data stored in a plurality of memory blocks, which are included in the volatile memory device, to the nonvolatile memory device by using the emergency power; and prohibiting a refresh operation upon a memory block of which back up is completed.

### BRIEF DESCRIPTION OF THE DRAWINGS

FIG. 1 is a block diagram of a memory module in accordance with an embodiment of the present invention.

FIG. 2 is a detailed diagram of a volatile memory device shown in FIG. 1.

FIGS. 3A and 3B are diagrams for describing operations of a refresh control unit shown in FIG. 2 in a first refresh mode.

FIGS. 4A and 4B are diagrams for describing operations of a refresh control unit shown in FIG. 2 in a second refresh mode.

FIGS. 5A and 5B are diagrams for describing operations of a refresh control unit shown in FIG. 2 in a third refresh mode.

FIG. 6 is a flow chart for describing an operation of the memory module shown in FIG. 1.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

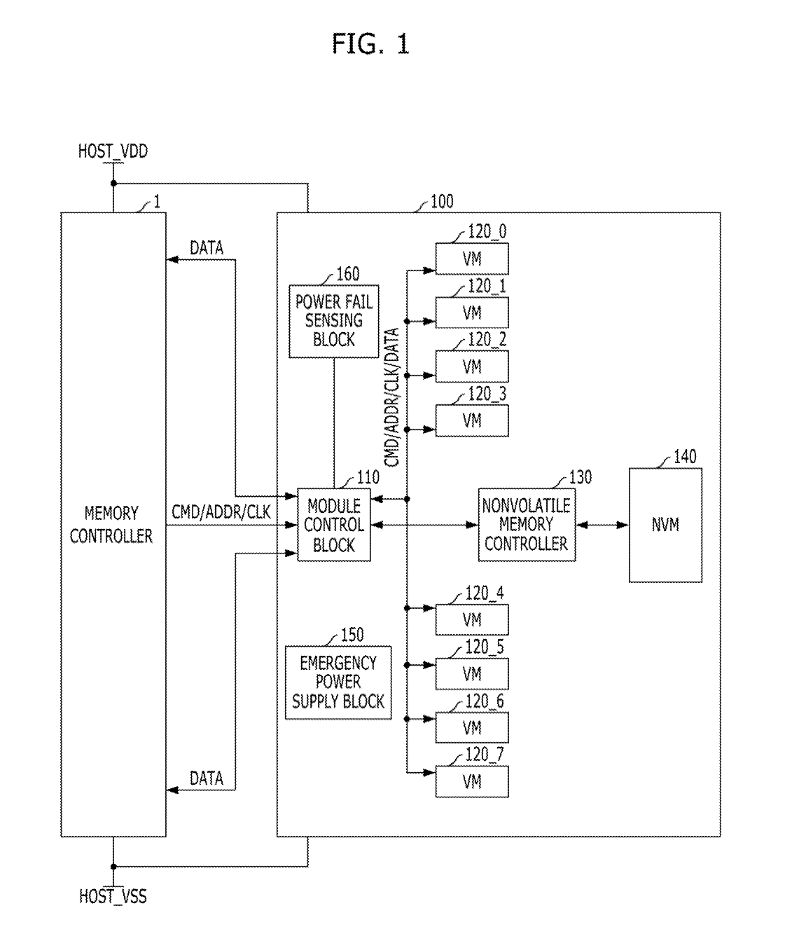

FIG. 1 is a block diagram illustrating a memory module 100 in accordance with an embodiment of the present invention.

Referring to FIG. 1, the memory module 100 may include a module control block 110, volatile memory devices 120_0 to 120_7, a nonvolatile memory controller 130, a nonvolatile memory device 140, an emergency power supply block 150, and a power fail sensing block 160.

The memory module 100 may prevent the loss of data even in a power failure, through an operation of backing up the data stored in the volatile memory devices (or chips) 120_0 to 120_7 to the nonvolatile memory device (or chip) 140 when the power of a host is unstable. For the sake of convenience in explanation, the memory module 100 is shown together with a memory controller 1 on the host (not shown), which transmits and receives data DATA and provides a command CMD, an address ADD and a clock CLK for controlling the memory module 100.

Each of the volatile memory devices 120_0 to 120_7 may be a dynamic random access memory (DRAM), and the nonvolatile memory device 140 may be a flash memory. However, each of the volatile memory devices 120_0 to 120_7 may be a different kind of volatile memory other than a DRAM, and the nonvolatile memory device 140 may be a different kind of nonvolatile memory other than a flash memory.

When powers HOST_VDD and HOST_VSS of the host are normal, the module control block 110 may buffer the command CMD, the address ADD and the clock CLK provided from the memory controller 1, and may provide them to the volatile memory devices 120_0 to 120_7. The module control block 110 may buffer the data DATA provided from the memory controller 1 and provide them to the volatile memory devices 120_0 to 120_7, or may buffer the data DATA provided from the volatile memory devices 120_0 to 120_7 and provide them to the memory controller 1. That is to say, when the powers HOST_VDD and HOST_VSS of the host are normal, the module control block 110 may perform the function of relaying communication between the volatile memory devices 120_0 to 120_7 and the memory controller 1.

If a fail in the host powers HOST_VDD and HOST_VSS is sensed by the power fail sensing block 160, that is, if instability in the power supply voltage HOST_VDD and the ground voltage HOST_VSS supplied from the host is sensed, the power fail sensing block 160 may interrupt the supply of the host powers HOST_VDD and HOST_VSS to the memory module 100, and may control the memory module 100 to operate using the power of the emergency power supply block 150. The emergency power supply block 150 may be realized using one or more power capacitors, for example, a super capacitor with large capacity, and may supply emergency power while the data of the volatile memory devices 120_0 to 120_7 are backed up to the nonvolatile memory device 140. Meanwhile, if a failure in the host powers HOST_VDD and HOST_VSS is sensed, the power fail sensing block 160 may inform the fail in the host powers HOST_VDD and HOST_VSS, to the module control block 110.

If the fail in the host powers HOST_VDD and HOST_VSS is informed, the module control block 110 may control the data stored in the volatile memory devices 120_0 to 120_7, to be backed up to the nonvolatile memory device 140. In detail, the module control block 110 may control the data stored in the volatile memory devices 120_0 to 120_7, to be read, by applying a command CMD, an address ADD and a clock CLK generated in itself, to the volatile memory devices 120_0 to 120_7, and may control the nonvolatile memory controller 130 in such a manner that the data read from the volatile memory devices 120_0 to 120_7 may be programmed (or written) in the nonvolatile memory device 140. The nonvolatile memory controller 130 may control the nonvolatile memory device 140 in such a manner that data DATA transferred from the module control block 110, that is, the data read from the volatile memory devices 120_0 to 120_7, may be programmed in the nonvolatile memory device 140.

The module control block 110 may perform a control task in such a manner that regions in the volatile memory devices 120_0 to 120_7, which are completely backed up, are excluded from refresh operations to reduce current consumption, while performing the operation for backing up the data of the volatile memory devices 120_0 to 120_7. This will be described later in detail with reference to the attached drawings.

The data of the volatile memory devices 120_0 to 120_7, which are backed up to the nonvolatile memory device 140 upon occurrence of the fail of the host powers HOST_VDD and HOST_VSS, may be transmitted to and recovered in the volatile memory devices 120_0 to 120_7 after the host powers HOST_VDD and HOST_VSS return to a normal state.

While it is shown in FIG. 1 that 8 volatile memory devices 120_0 to 120_7 and 1 nonvolatile memory device 140 are provided in the memory module 100, this is only an example and any number of volatile and nonvolatile memory devices may be provided, so long as there is at least one of each. Also, while it is shown in FIG. 1 that the data of the volatile memory devices 120_0 to 120_7 is transferred to the nonvolatile memory device 140 through the module control block 110 and the nonvolatile memory controller 130, data may be directly transmitted between the volatile memory devices 120_0 to 120_7 and the nonvolatile memory device 140 when the data transmission protocols of the volatile memory devices 120_0 to 120_7 and the nonvolatile memory device 140 are designed to be compatible with each other. Moreover, it is to be noted that the components shown in FIG. 1 mean functional classification but do not mean physical distinguishment. For example, while each of the components shown in FIG. 1 may be implemented with one semiconductor chip, two or more components shown in FIG. 1 may be integrated in a single semiconductor chip.

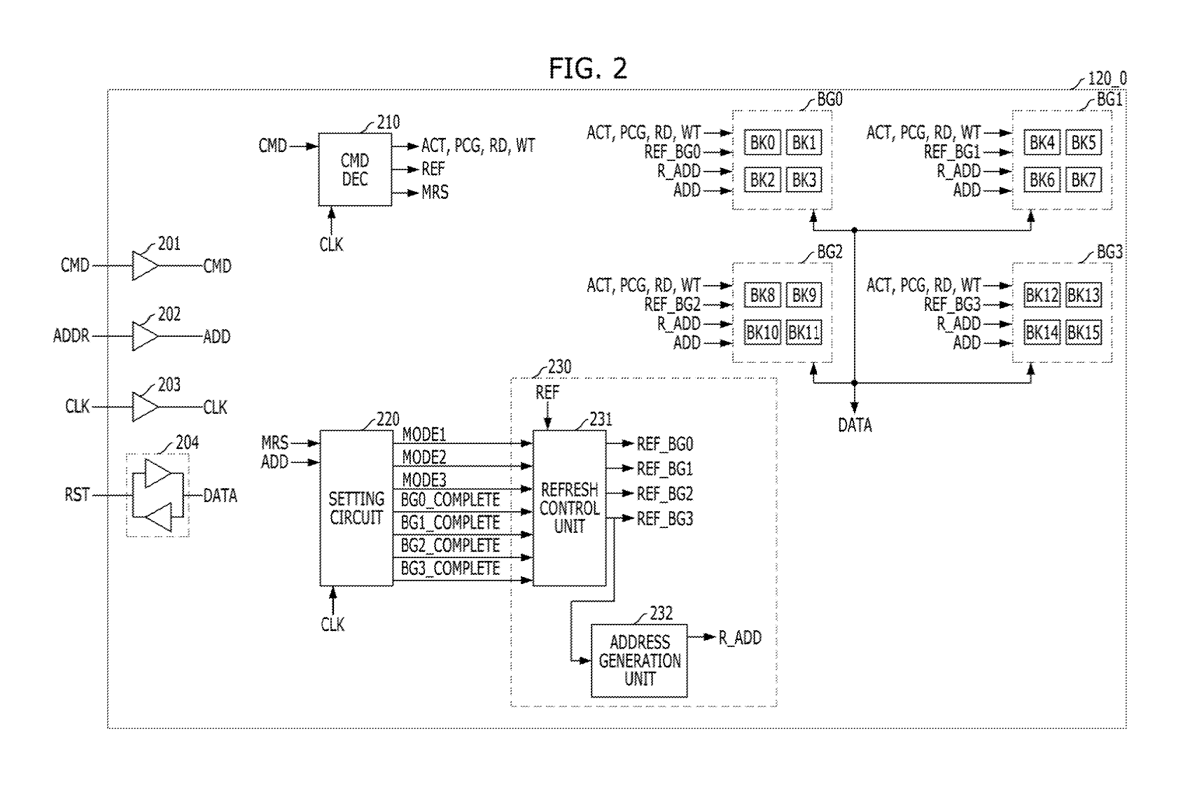

FIG. 2 is a detailed diagram of the volatile memory device 120_0 shown in FIG. 1. The other volatile memory devices 120_1 to 120_7 may have the same configuration as in FIG. 2.

Referring to FIG. 2, the volatile memory device 120_0 may include a command reception unit 201, an address reception unit 202, a clock reception unit 203, a data transmission/reception unit 204, a command decoder 210, a setting circuit 220, a refresh circuit 230, and memory blocks BG0 to BG3.

The command reception unit 201 may receive the command CMD configured by multi-bit signals. The command CMD may include a row address strobe (RAS) signal, a column address strobe (CAS) signal, an active (ACT) signal, and a chip select (CS) signal. The address reception unit 202 may receive the address ADD configured by multi-bit signals. The clock reception unit 203 may receive the clock CLK. The clock CLK received by the clock reception unit 203 may include a clock and a complementary clock. The clock CLK received by the clock reception unit 203 may be used for a synchronized operation of the volatile memory device 120_0. The data transmission/reception unit 204 may receive the data inputted from an exterior and transfer the received data to the memory blocks BG0 to BG3, or may transmit the data outputted from the memory blocks BG0 to BG3, to the exterior. The data received through the data transmission/reception unit 204 may be write data, and the data transmitted through the data transmission/reception unit 204 may be read data.

The command decoder 210 may decode the command CMD received through the command reception unit 201, and may generate various internal commands REF, MRS, ACT, PCG, RD and WT. The internal commands generated by the command decoder 210 may include an internal refresh command REF for directing a refresh operation, an internal setting command MRS (mode register set) for directing a setting operation, an internal active command ACT for directing an active operation, an internal precharge command PCG for directing a precharge operation, an internal read command RD for directing a read operation, and an internal write command WT for directing a write operation.

The setting circuit 220 may decode the address ADD received through the address reception unit 202, when the internal setting command MRS is activated, and may generate various signals. The signals generated by the setting circuit 220 may include refresh mode signals MODE1, MODE2 and MODE3 for setting refresh modes, and backup completion signals BG0_COMPLETE to BG3_COMPLETE indicating that backup operations for the memory blocks BG0 to BG3 are completed. The setting circuit 220 may generate signals (not shown) for setting various internal voltage levels, setting various delay values and setting various modes.

The refresh circuit 230 may control the refresh operations of the memory blocks BK0 to BK3 in response to the internal refresh command REF. A scheme for the refresh circuit 230 to control the refresh operations of the memory blocks BG0 to BG3 may be different according to a refresh mode that is set. The refresh circuit 230 may perform a control task in such a manner that a refresh operation is not performed for a memory block that is completely backed up, among the memory blocks BG0 to BG3. For example, when the backup of the memory blocks BG0 and BG1 is completed, refresh operations may be performed for only the memory blocks BG2 and BG3, and the memory blocks BG0 and BG1 may be excluded from refresh operations.

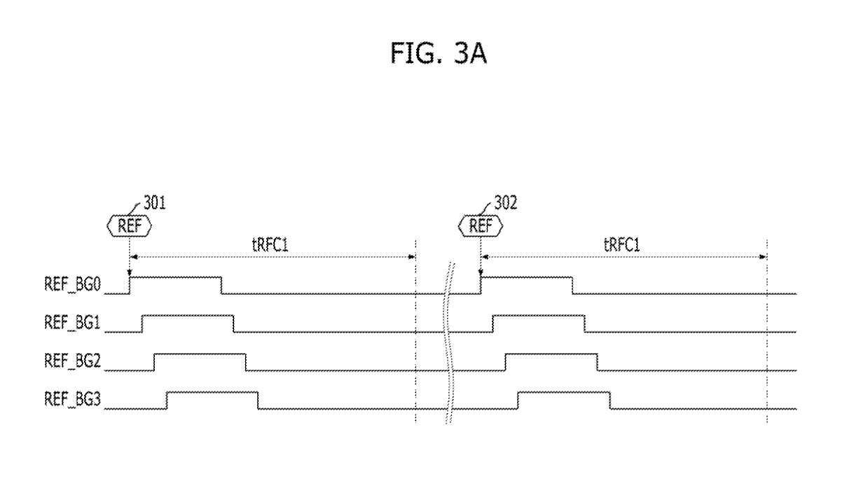

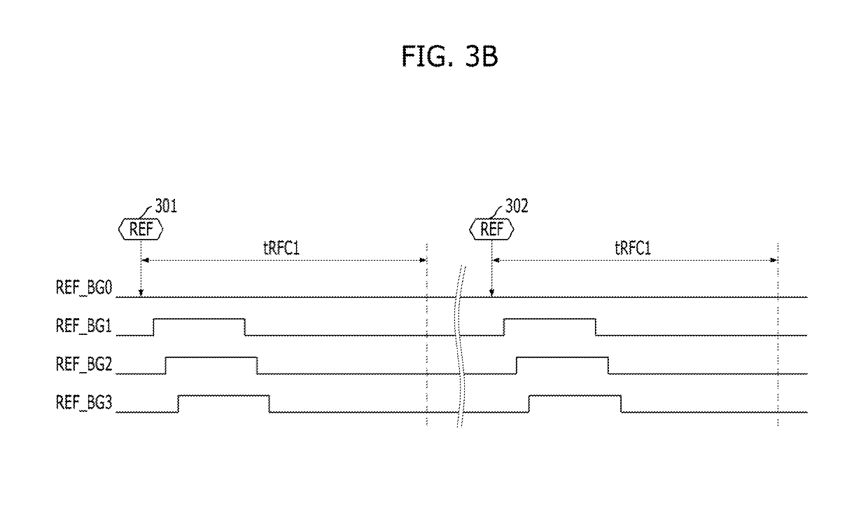

The refresh circuit 230 may include a refresh control unit 231 and an address generation unit 232. The refresh control unit 231 may generate a plurality of refresh signals REF_BG0 to REF_BG3 in a sequence determined according to a set refresh mode each time the Internal refresh command REF is activated. Schemes for the refresh control unit 231 to activate the refresh signals REF_BG0 to REF_BG3 according to set refresh modes will be described later with reference to FIGS. 3A to 5B. The respective refresh signals REF_BG0 to REF_BG3 correspond to the respective memory blocks BG0 to BG3. If the refresh signals REF_BG0 to REF_BG3 are activated, refresh operations may be performed in the corresponding memory blocks BG0 to BG3. For example, if the refresh signal REF_BG1 is activated, the refresh operation may be performed in the memory block BG1, and, if the refresh signal REF_BG3 is activated, the refresh operation may be performed in the memory block BG3. The refresh control unit 231 may not activate a refresh signal corresponding to a memory block that is completely backed up, among the memory blocks BG0 to BG3. While a corresponding backup completion signal is activated when the backup of a memory block is completed, the refresh control unit 231 may not activate a refresh signal for the corresponding memory block when the backup completion signal is activated. For example, if the backup completion signal BG1_COMPLETE is activated, the refresh signal REF_BG1 may not be activated even though the internal refresh command REF is activated. The address generation unit 232 changes the value of a refresh address R_ADD, which is transferred to the memory blocks BG0 to BG3, each time a predetermined refresh signal REF_BG3 is activated among the refresh signals REF_BG0 to REF_BG3. For example, the address generation unit 232 may increase the value of the refresh address R_ADD by 1 each time the refresh signal REF_BG3 is activated. The predetermined refresh signal may be any one refresh signal among the refresh signals REF_BG0 to REF_BG3. However, since a stable operation may be ensured when the refresh address R_ADD is changed after all the memory blocks BG0 to BG3 are refreshed once, the refresh signal activated last among the refresh signals REF_BG0 to REF_BG3 may be the refresh signal, which is inputted to the address generation unit 232. The refresh signal REF_BG3 is not activated prior to the other refresh signals REF_BG0 to REF_BG2 in any refresh modes. That is, the refresh signal REF_BG3 is activated at least simultaneously with another refresh signal or is activated last, and thus the refresh signal REF_BG3 may be the refresh signal that is activated last among the refresh signals REF_BG0 to REF_BG3.

Each of the memory blocks BG0 to BG3 may include at least one bank. While it is shown that 16 banks BK0 to BK15 exist in the volatile memory device 120_0, 4 banks are classified into one memory block and a total 4 memory blocks BG0 to BG3 are formed, the numbers of memory blocks and banks may be freely changed according to a design. The memory blocks BG0 to BG3 may be refreshed in response to the respective refresh signals REF_BG0 to REF_BG3. For example, if the refresh signal REF_BG0 is activated, the rows selected by the refresh address R_ADD in all the banks BK0 to BK3 of the memory block BG0 may be refreshed. Similarly, if the refresh signal REF_BG2 is activated, the rows selected by the refresh address R_ADD in all the banks BK8 to BK11 of the memory block BG2 may be refreshed. The memory blocks BG0 to BG3 may perform the active, precharge, read and write operations in response to the address ADD and the internal commands ACT, PCG, RD and WT.

While it is shown in FIG. 2 that the refresh operations are controlled in a unit of bank groups, the unit by which the refresh operations are controlled and the refresh operations are prohibited may be a bank. In other words, refresh signals, for example, REF_BK0 to REF_BK15, may exist by the units of banks, and backup completion signals, for example, BK0_COMPLETE to BK15_COMPLETE, may also exist by the units of banks.

FIGS. 3A and 3B are diagrams for describing operations of the refresh control unit 231 in a first refresh mode in which the refresh mode signal MODE1 is activated. FIG. 3A shows operations of the refresh control unit 231 in the case where a memory block, which is completely backed up, does not exist, and FIG. 3B shows operations of the refresh control unit 231 in the case where backup of the memory block BG0 is completed.

In the first refresh mode, the refresh control unit 231 may activate the refresh signals REF_BG0 to REF_BG3 corresponding to the entire memory blocks BG0 to BG3 each time the refresh command REF is activated. Referring to FIG. 3A, it may be seen that the refresh signals REF_BG0 to REF_BG3 corresponding to the entire memory blocks BG0 to BG3 are activated in response to the application of a refresh command 301. Also, it may be seen that the refresh signals REF_BG0 to REF_BG3 are activated in response to the application of a refresh command 302. Upon the application of the refresh command 302, rows next to the rows having been refreshed upon the application of the refresh command 301 may be refreshed. For example, if 100^{th} rows have been refreshed in the memory blocks BG0 to BG3 upon the application of the refresh command 301, 101^{st} rows may be refreshed in the memory blocks BG0 to BG3 upon the application of the refresh command 302. In the first refresh mode, since all the memory blocks BG0 to BG3 are refreshed each time the refresh command REF is applied once, a refresh operation period, that is, a refresh cycle tRFC, may be set to be relatively long. For reference, while it may be seen that the refresh signals REF_BG0 to REF_BG3 are activated with a slight time interval, this is to prevent peak current from increasing by the refresh operations. Unlike FIG. 3A, the refresh signals REF_BG0 to REF_BG3 may be simultaneously activated.

FIG. 3B shows the operations of the refresh control unit 231 when the backup completion signal BG0_COMPLETE is activated in the first refresh mode. Referring to FIG. 3B, it may be seen that, while the refresh signals REF_BG1 to REF_BG3 are activated in response to the application of refresh commands 301 and 302, the refresh signal REF_BG0 is not activated. Similarly, when the backup completion signals BG1_COMPLETE to BG3_COMPLETE are activated, the corresponding refresh signals REF_BG1 to REF_BG3 may not be activated.

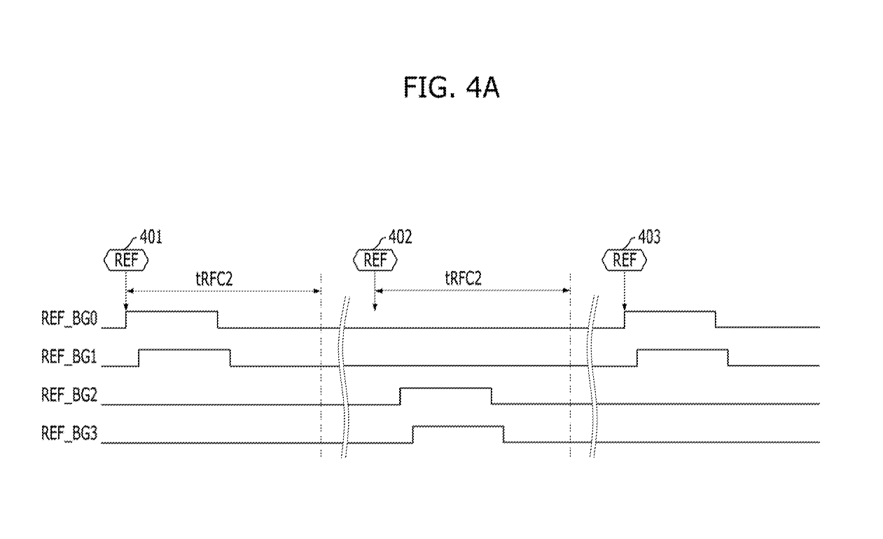

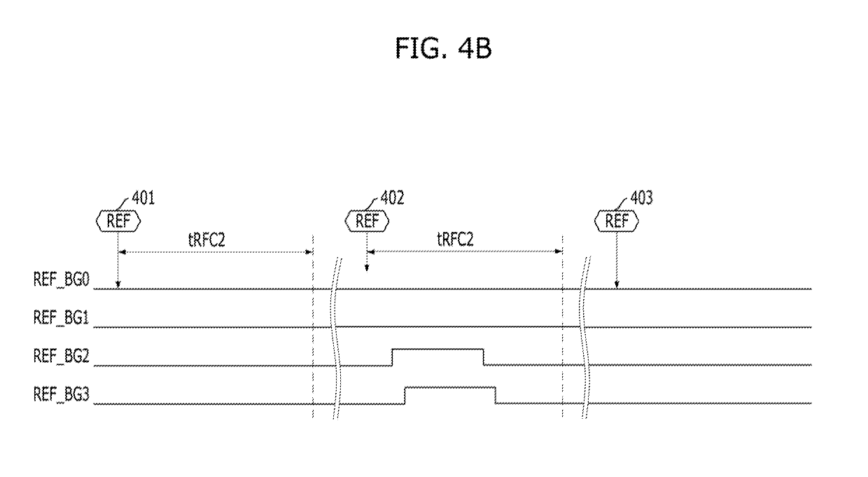

FIGS. 4A and 4B are diagrams for describing operations of the refresh control unit 231 in a second refresh mode in which the refresh mode signal MODE2 is activated. FIG. 4A shows operations of the refresh control unit 231 in the case where a memory block, which is completely backed up, does not exist, and FIG. 4B shows operations of the refresh control unit 231 in the case where backup of the memory blocks BG0 and BG1 is completed.

In the second refresh mode, the refresh control unit 231 may activate refresh signals corresponding to one half memory blocks among the entire memory blocks BG0 to BG3 each time the refresh command REF is activated. Referring to FIG. 4A, it may be seen that the refresh signals REF_BG0 and REF_BG1 corresponding to the memory blocks BG0 and BG1 are activated in response to the application of a refresh command 401 and the refresh signals REF_BG2 and REF_BG3 corresponding to the memory blocks BG2 and BG3 are activated in response to the application of a refresh command 402. When a refresh command 403 is applied next to the refresh command 402, the memory blocks BG0 and BG1 may be refreshed again. At this time, the rows refreshed in the memory blocks BG0 and BG1 may be rows next to the rows having been refreshed upon the application of the refresh command 401. In the second refresh mode, since half of the memory blocks BG0 to BG3 are refreshed each time the refresh command REF is applied once, a refresh operation period, that is, a refresh cycle tRFC, may be set to be shorter than in the first refresh mode.

FIG. 4B shows the operations of the refresh control unit 231 when the backup completion signals BG0_COMPLETE and BG1_COMPLETE are activated in the second refresh mode. Referring to FIG. 4B, it may be seen that the refresh signals REF_BG0 and REF_BG1 are not activated although refresh commands 401 and 403 are applied.

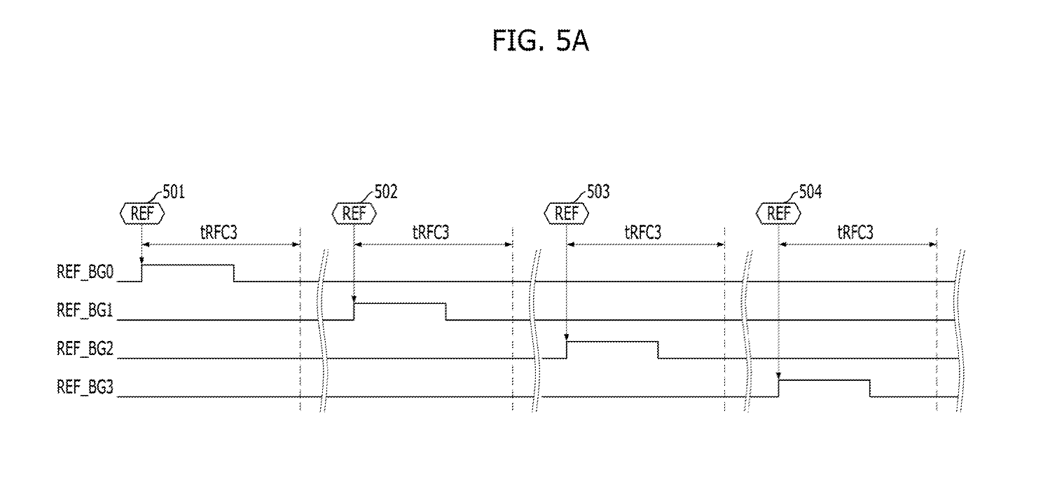

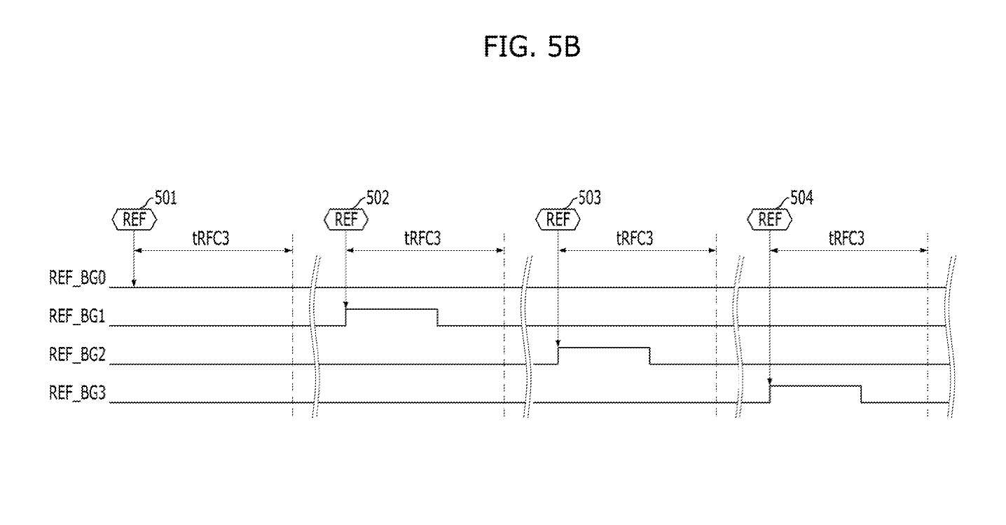

FIGS. 5A and 5B are diagrams for describing operations of the refresh control unit 231 in a third refresh mode in which the refresh mode signal MODE3 is activated. FIG. 5A shows operations of the refresh control unit 231 in the case where a memory block, which is completely backed up, does not exist, and FIG. 5B shows operations of the refresh control unit 231 in the case where backup of the memory block BG0 is completed.

In the third refresh mode, the refresh control unit 231 may activate a refresh signal corresponding to a quarter (¼th) of the memory blocks BG0 to BG3 each time the refresh command REF is activated. Referring to FIG. 5A, the refresh signal REF_BG0 may be activated in response to the application of a refresh command 501, the refresh signal REF_BG1 may be activated in response to the application of a refresh command 502, the refresh signal REF_BG2 may be activated in response to the application of a refresh command 503, and the refresh signal REF_BG3 may be activated in response to the application of a refresh command 504. If a refresh command (not shown) next to the refresh command 504 is applied, the refresh signal REF_BG0 may be activated again. At this time, the rows refreshed in the memory block BG0 may be rows next to the rows having been refreshed upon the application of the refresh command 501. In the third refresh mode, since a quarter of the memory blocks BG0 to BG3 are activated each time the refresh command REF is applied once, a refresh operation period, that is, a refresh cycle tRFC, may be set to be shorter than in the second refresh mode.

FIG. 5B shows the operations of the refresh control unit 231 when the backup completion signal BG0_COMPLETE is activated in the third refresh mode. Referring to FIG. 5B, it may be seen that the refresh signal REF_BG0 is not activated although a refresh command 501 is applied.

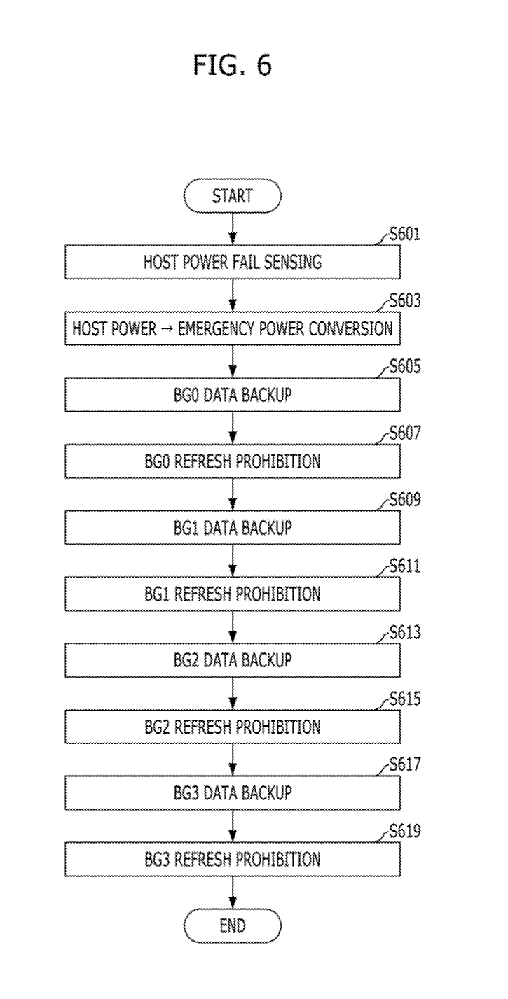

FIG. 6 is a flow chart for describing an operation of the memory module 100 shown in FIG. 1. FIG. 6 shows a process in which the data stored in the volatile memory device 120_0 are backed up to the nonvolatile memory device 140 when a host power fail occurs. The data of the other volatile memory devices 120_1 to 120_7 may be backed up in the same manner as the data of the volatile memory device 120_0.

Referring to FIG. 6, first, a failure of the host powers HOST_VDD and HOST_VSS may be sensed at step S601. The failure of the host powers HOST_VDD and HOST_VSS may be sensed by the power fail sensing block 160. The failure of the host powers HOST_VDD and HOST_VSS may denote that the host powers HOST_VDD and/or HOST_VSS are so unstable that the memory module 100 may not correctly operate.

After the failure of the host powers HOST_VDD and HOST_VSS is sensed, the memory module 100 may convert power to be used, from the unstable host powers HOST_VDD and HOST_VSS to the emergency power supplied by the emergency power supply block 150 at step S603.

Then, a backup operation is started.

First, the data of the memory block BG0 of the volatile memory device 120_0 may be backed up to the nonvolatile memory device 140 at step S605. That is, an operation of reading the data of the memory block BG0 is performed in the volatile memory device 120_0 and an operation of programming (or writing) the data read from the memory block BG0 is performed in the nonvolatile memory device 140. To prevent the data stored in the volatile memory device 120_0 from being lost while the data of the volatile memory device 120_0 is backed up, a refresh operation may be periodically performed.

After the data of the memory block BG0 is backed up to the nonvolatile memory device 140, the refresh operation of the memory block BG0 may be prohibited at step S607. The prohibition of the refresh operation of the memory block BG0 may be performed by applying the command CMD to activate the internal setting command MRS in the volatile memory device 120_0, applying the address ADD of a specified combination, and thereby activating the backup completion signal BG0_COMPLETE.

After the refresh operation of the memory block BG0 is prohibited, the data of the memory block BG1 may be backed up to the nonvolatile memory device 140 at step S609. Even while the data of the memory block BG1 is backed up, a refresh operation may be periodically performed in the nonvolatile memory device 140. However, a refresh operation is not performed in the memory block BG0. Because the data of the memory block BG0 was already completely backed up to the nonvolatile memory device 140, no concern is caused even when the data of the memory block BG0 is lost.

After the data of the memory block BG1 is backed up to the nonvolatile memory device 140, the refresh operation of the memory block BG1 may be prohibited at step S611. The prohibition of the refresh operation of the memory block BG1 may be implemented by applying the command CMD to activate the internal setting command MRS in the volatile memory device 120_0, applying the address ADD of a specified combination, and thereby activating the backup completion signal BG1_COMPLETE.

After the refresh operation of the memory block BG1 is prohibited, the data of the memory block BG2 may be backed up to the nonvolatile memory device 140 at step S613. Even while the data of the memory block BG2 is backed up, a refresh operation may be periodically performed in the nonvolatile memory device 140. However, refresh operations are not performed in the memory blocks BG0 and BG1. Because the data of the memory blocks BG0 and BG1 was already completely backed up to the nonvolatile memory device 140, no concern is caused even when the data of the memory blocks BG0 and BG1 is lost.

After the data of the memory block BG2 is backed up to the nonvolatile memory device 140, the refresh operation of the memory block BG2 may be prohibited at step S615. The prohibition of the refresh operation of the memory block BG2 may be implemented by applying the command CMD to activate the internal setting command MRS in the volatile memory device 120_0, applying the address ADD of a specified combination, and thereby activating the backup completion signal BG2_COMPLETE.

After the refresh operation of the memory block BG2 is prohibited, the data of the memory block BG3 may be backed up to the nonvolatile memory device 140 at step S617. Even while the data of the memory block BG3 is backed up, a refresh operation may be periodically performed in the nonvolatile memory device 140. However, refresh operations are not performed in the memory blocks BG0, BG1 and BG2. Because the data of the memory blocks BG0, BG1 and BG2 was already completely backed up to the nonvolatile memory device 140, no concern is caused even when the data of the memory blocks BG0, BG1 and BG2 is lost.

After the data of the memory block BG3 is backed up to the nonvolatile memory device 140, the refresh operation of the memory block BG3 may be prohibited at step S619. Then, since the refresh operations of all the memory blocks BG0 to BG3 are prohibited, a refresh operation is not performed in the volatile memory device 120_0 even when the refresh command REF is applied to the volatile memory device 120_0.

The data backed up to the nonvolatile memory device 140 in this way may be transmitted back to and stored in the volatile memory device 120_0 after the host powers HOST_VDD and HOST_VSS have recovered.

According to the backup scheme of FIG. 6, a refresh operation of a memory block is prohibited immediately when the backup of the memory block is completed. Since it may not be necessary to conserve the data of the memory block, which is completely backed up, no concern is caused due to loss of the data, and the amount of power consumed in the refresh operation may be reduced as the memory block that is completely backed up is excluded from the refresh operation. Accordingly, the amount of power that is consumed by the memory module 100 for backup of data may be minimized. Accordingly, the capacity of the emergency power supply block 150 mounted to the memory module 100 may be decreased, and thus the fabrication cost of the memory module 100 may be reduced.

According to the embodiments, the data of a volatile memory may be backed up to a nonvolatile memory while using a minimum amount of power.

Although various embodiments have been described for illustrative purposes, it will be apparent to those skilled in the art that various changes and modifications may be made without departing from the spirit and scope of the invention as defined in the following claims.

What is claimed is:

1. A volatile memory device comprising:
a plurality of memory blocks suitable for being refreshed in response to a plurality of refresh signals, respectively;
a command decoder suitable for decoding a command to generate an internal refresh command; and
a refresh circuit suitable for generating the refresh signals in response to the internal refresh command, wherein the refresh circuit prohibits a refresh signal corresponding to a memory block of which backup is completed from activating.

2. The volatile memory device according to claim 1, wherein the refresh circuit comprises:
a refresh control unit suitable for controlling the refresh signals to be activated in a predetermined sequence according to a set refresh mode when the internal refresh command is activated while not activating the refresh signal corresponding to the memory block of which backup is completed; and
an address generation unit suitable for generating a refresh address to be used in a refresh operation.

3. The volatile memory device according to claim 2, wherein the address generation unit changes a value of the refresh address when a predetermined one of the refresh signals is activated.

4. The volatile memory device according to claim 1, wherein information on the memory block of which backup is completed is inputted from an exterior of the volatile memory device.

5. The volatile memory device according to claim 1, wherein each of the memory blocks includes a bank group.

6. The volatile memory device according to claim 1, wherein each of the memory blocks includes a bank.

7. A memory module comprising:
an emergency power;
a volatile memory device including a plurality of memory blocks;
a nonvolatile memory device; and
a module control block suitable for controlling data of the volatile memory device to be backed up to the nonvolatile memory device by using the emergency power when a power failure occurs,
wherein data of the memory blocks are sequentially backed up to the nonvolatile memory device, and a refresh operation is prohibited for a memory block of which backup is completed.

8. The memory module according to claim 7, wherein the power failure includes a failure of a host power of the memory module.

9. The memory module according to claim 8, further comprising:
a power fail sensing block suitable for sensing the failure of the host power.

10. The memory module according to claim 9, wherein the emergency power includes at least one power capacitor.

11. The memory module according to claim 7, wherein the volatile memory device comprises:
the memory blocks suitable for being refreshed in response to a plurality of refresh signals, respectively;
a command decoder suitable for decoding a command to generate an internal refresh command; and
a refresh circuit suitable for generating the refresh signals in response to the internal refresh command, wherein the refresh circuit does not activate a refresh signal corresponding to the memory block of which backup is completed, among the plurality of memory blocks.

12. The memory module according to claim 11, wherein the refresh circuit comprises:
a refresh control unit suitable for controlling the refresh signals to be activated in a predetermined sequence according to a set refresh mode when the internal refresh command is activated while not activating the refresh signal corresponding to the memory block of which backup is completed; and
an address generation unit suitable for generating a refresh address to be used in a refresh operation.

13. The memory module according to claim 12, wherein the address generation unit changes a value of the refresh address when a predetermined one of the refresh signals is activated.

14. The memory module according to claim 11, wherein information on the memory block of which backup is completed is transferred from the module control block to the volatile memory device.

15. The memory module according to claim 11, wherein each of the memory blocks includes a bank group.

16. The memory module according to claim 11, wherein each of the memory blocks includes a bank.

17. A method of operating a memory module including a volatile memory device and a nonvolatile memory device, the method comprising:
sensing a failure of a host power;
converting a power to be used by the memory module, from the host power to an emergency power;
backing up sequentially data stored in a plurality of memory blocks, which are included in the volatile memory device, to the nonvolatile memory device by using the emergency power; and
prohibiting a refresh operation upon a memory block of which backup is completed.

18. The method according to claim 17, further comprising:
recovering the data backed up to the nonvolatile memory device, to the memory blocks of the volatile memory device, when the host power is recovered.

19. The operation method according to claim 17, wherein a refresh operation is not performed for the memory block of which refresh operation is prohibited, even when a refresh command is applied to the volatile memory device.

20. The operation method according to claim 17, further comprising:
performing refresh operations on the other memory blocks other than the memory block of which backup is completed.
